(19) United States
(12) Patent Application Publication
(10) Pub. No.: US 2016/0164020 A1
(43) Pub. Date: Jun. 9, 2016

(54) ORGANIC LIGHT-EMITTING DEVICE

(71) Applicant: Seoul National University R&DB Foundation, Seoul (KR)

(72) Inventors: Jang Joo KIM, Seoul (KR); Jin Won SUN, Seoul (KR); Jeong Hwan LEE, Seoul (KR); Kwon Hyeon KIM, Changwon-si (KR)

(21) Appl. No.: 14/957,152

(22) Filed: Dec. 2, 2015

(30) Foreign Application Priority Data
Dec. 4, 2014 (KR) 10-2014-0173253

(51) Int. Cl. H01L 51/50; C09K 11/02; C09K 11/06

(52) U.S. Cl. CPC H01L 51/5028; H01L 51/5056; H01L 51/5072; C09K 11/06; C09K 11/025; H01L 51/0072

(57) ABSTRACT

An organic light-emitting device includes a first electrode, a second electrode facing the first electrode, and an emission layer that is disposed between the first electrode and the second electrode and includes a mixed host and a dopant, wherein the mixed host includes a hole transporting host and an electron transporting host which together form an exciplex, and the dopant includes a compound that emits delayed fluorescent light.

### CROSS-REFERENCE TO RELATED APPLICATION

This application claims the benefit of Korean Patent Application No. 10-2014-0173253, filed on Dec. 4, 2014, in the Korean Intellectual Property Office, the disclosure of which is incorporated herein in its entirety by reference.

### BACKGROUND

1. Field

One or more exemplary embodiments relate to an organic light-emitting device, and more particularly, to an organic light-emitting device including a host that form an exciplex and a dopant.

2. Description of the Related Art

Under electrical excitation conditions, singlet excitons and triplet excitons are generated at a ratio of 25% to 75%. Thus, in order to increase electroluminescence efficiency by converting all the singlet excitons and the triplet excitons in an organic light-emitting device to light, it has been known that using a phosphorescent material as a luminary material is essential. Recently, there has been a publication regarding an organic light-emitting device having 100% internal quantum efficiency (IQE) by using a phosphorescent dopant.

Most phosphorescent dopants having high luminescent efficiency are a heavy metal complex capable of spin-orbit coupling. However, a phosphorescent material emitting deep blue light is unstable and rapidly degradable. Thus, it is difficult to synthesize a phosphorescent material of deep blue color, which has a high efficiency and a long lifespan. However, a fluorescent material is stable, may be synthesized at a low cost, and has an increased long lifespan. Whereas, a general fluorescent material has been regarded as difficult to have a high luminescent efficiency that is the same as that of a phosphorescent material.

In recent years, public attention has been drawn to studies for using delayed fluorescence to compensate for the disadvantages of a fluorescent material. Triplet-triplet annihilation (TTA) and reverse inter-system crossing (RISC), in which a triplet converts to a singlet, belong to mechanisms of delayed fluorescence.

TTA may generate additional singlet excitons that increase efficiency to about 15% to about 37.5% according to up-conversion mechanism. The maximum internal quantum efficiency that may be obtained through TTA is expected to about 40% to about 62.5%, but this is far from 100% of the internal quantum efficiency.

RISC is a mechanism that provides an increased amount of excitons by up-converting excitons from a triplet excitation state (T1) to a singlet excitation state (S1) by thermal activation energy. When RISC occurs without loss, 100% of internal quantum efficiency may be achieved. However, the highest external quantum efficiency that has been recorded up-to-date as an organic light-emitting device using a delayed fluorescent material by RISC is 19.3%, which is lower than 30% of an external luminescent efficiency using a phosphorescent material, and indicates that internal luminescent efficiency has not yet reached 100%. Therefore, another method of increasing electroluminescence efficiency needs to be developed.

### SUMMARY

One or more exemplary embodiments include an organic light-emitting device having high external quantum efficiency and improved roll-off characteristics.

Additional aspects will be set forth in part in the description which follows and, in part, will be apparent from the description, or may be learned by practice of the presented embodiments.

According to one or more exemplary embodiments, an organic light-emitting device includes a first electrode; a second electrode facing the first electrode; and an emission layer that is disposed between the first electrode and the second electrode and includes a mixed host and a dopant, wherein the mixed host includes a hole transporting host and an electron transporting host which together form an exciplex, and the dopant includes a compound that emits delayed fluorescent light.

Triplet excitation energy of the dopant may be lower than triplet excitation energy of the exciplex, and an overlapping area formed by curves of an absorption spectrum of the dopant and an emission spectrum of the exciplex may be large.

Triplet excitation energy of the dopant may be lower than triplet excitation energy of the hole transporting host and triplet excitation energy of the electron transporting host.

Singlet excitation energy of the dopant may be higher than triplet excitation energy of the dopant.

The dopant in the emission layer may include a delayed fluorescent organic material in the form of D-C-A (an electron donating group:D-a connecting group:C-an electron accepting group:A), in the form of D-C-A-C-D, or in the form of A-C-D-C-A.

The hole transporting host may include an aromatic amine compound or a carbazole derivative.

The electron transporting host may include a π-electron poor heteroaromatic ring.

The electron transporting host may include a phosphine oxide group-containing compound, a triazine derivative, or a sulfur oxide group-containing compound.

A hole transporting region may be further disposed between the first electrode and the emission layer.

An electron transporting region may be further disposed between the emission layer and the second electrode.

The hole transporting region may further include the hole transporting host.

The electron transporting region may further include the electron transporting host.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view schematically illustrating an organic light-emitting device according to an embodiment;

FIG. 2 is a cross-sectional view schematically illustrating an organic light-emitting device according to another embodiment;

FIGS. 3A and 3B are, each respectively, views of layer structures of organic light-emitting devices prepared in Examples 1 and 2 with highest occupied molecular orbital (HOMO) and lowest occupied molecular orbital (LUMO) energy;

FIG. 4A is an energy diagram showing triplet excitation levels (T1) of an exciplex host and a dopant used in the organic light-emitting device prepared in Example 1;

FIG. 4B is an energy diagram showing triplet excitation levels (T1) of an exciplex host and a dopant used in the organic light-emitting device prepared in Example 2;

FIG. 5 shows an absorption spectrum of 4CzIPN and a photoluminescence spectrum of a mCP:B3PYMPM exciplex and a TCTA:B3PYMPM exciplex;

FIG. 6 shows luminescent spectra of the organic light-emitting devices prepared in Examples 1 and 2;

FIG. 7 shows a graph of a current density verses a voltage and a graph of a voltage verses a luminescence of the organic light-emitting devices prepared in Examples 1 and 2;

FIG. 8 shows a graph of an external quantum efficiency and an electrical power efficiency of the organic light-emitting devices prepared in Examples 1 and 2; and

FIG. 9 is an electroluminescence decay curve of the organic light-emitting device prepared in Example 1.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

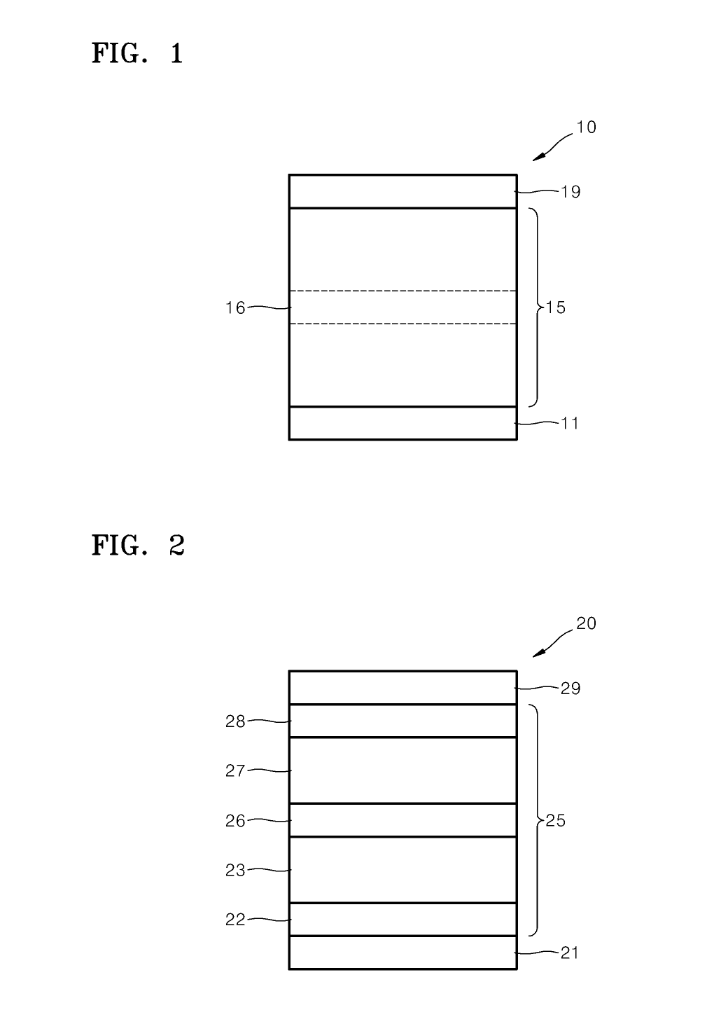

FIG. 1 is a cross-sectional view schematically illustrating an organic light-emitting device 10 according to an exemplary embodiment.

According to an exemplary embodiment, the organic light-emitting device 10 includes a first electrode 11, a second electrode 19 facing the first electrode 11, and an organic layer 15 that is disposed between the first electrode 11 and the second electrode 19. The organic layer 15 includes an emission layer 16 that includes a mixed host and a dopant.

The mixed host includes a hole transporting host and an electron transporting host which together form an exciplex, and the dopant includes a compound that emits delayed fluorescent light.

The first electrode 11 of the organic light-emitting device 10 may be an anode to which a positive (+) voltage is applied, and the second electrode 19 may be a cathode to which a negative (−) voltage is applied. Alternatively, the first electrode 11 may be a cathode, and the second electrode 19 may be an anode. However, for convenience of explanation, embodiments herein are described with the case including the first electrode 11 as an anode and the second electrode 19 as a cathode.

When a voltage is applied to the first electrode 11 and the second electrode 19 of the organic light-emitting device 10, in the organic layer 15, holes are transported by the hole transporting host, and electrons are transported by the electron transporting host, thereby generating excitons in the emission layer 16. Since a mixture of the hole transporting host having hole transporting characteristics and the electron transporting host having electron transporting characteristics is used as a host of the emission layer 16, a driving voltage may be reduced without an energy barrier when the holes and electrons are injected to the emission layer 16.

The organic layer 15 may include a hole transporting region between the emission layer 16 and the first electrode 11; and an electron transporting region between the emission layer 16 and the second electrode 19. The hole transporting region is a region related to injection and transport of holes from the first electrode 11 as the anode to the emission layer 16, and the electron transporting region is a region related to injection and transport of electrons from the second electrode 19 as the cathode to the emission layer 16.

Examples of the hole transporting host that may form an exciplex may include a carbazole derivative or an aromatic amine compound. The hole transporting host may include, for example, 1,3-bis(9-carbazolyl)benzene (mCP), tris(4-carbazoyl-9-ylphenyl)amine) (TCTA), 4,4′-Bis(N-carbazolyl)-1,1′-biphenyl (CBP), 3,3-bis(carbazol-9-yl)biphenyl (mCBP), N,N′-di(1-naphthyl)-N,N′-diphenyl-(1,1′-biphenyl)-4,4′-diamine) (NPB), 4,4′,4″-tris[phenyl(m-tolyl)amino]triphenylamine (m-MTDATA), or N,N′-bis(3-methylphenyl)-N,N′-diphenylbenzidine (TPD), but embodiments are not limited thereto.

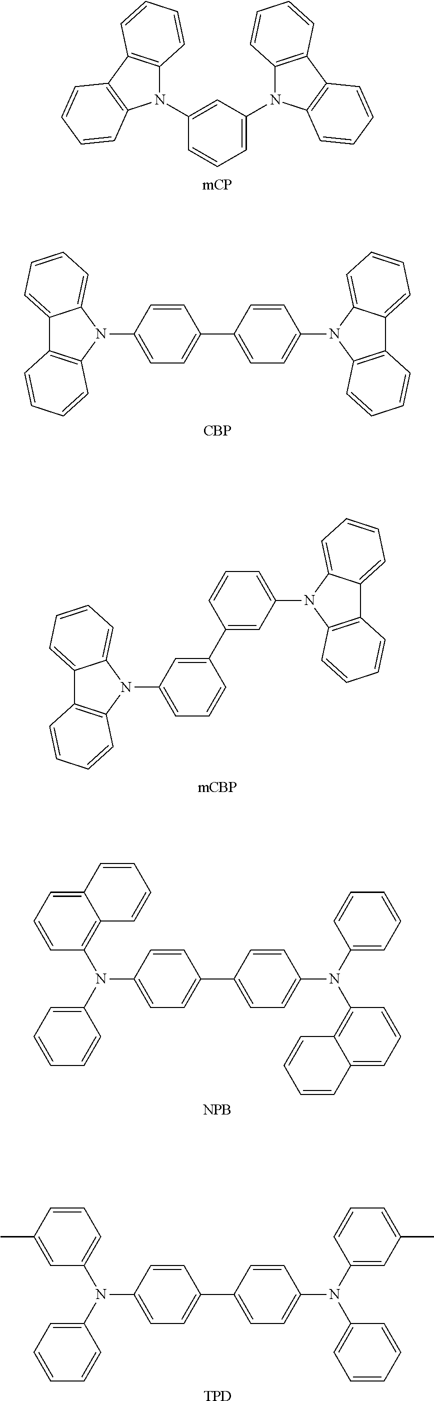

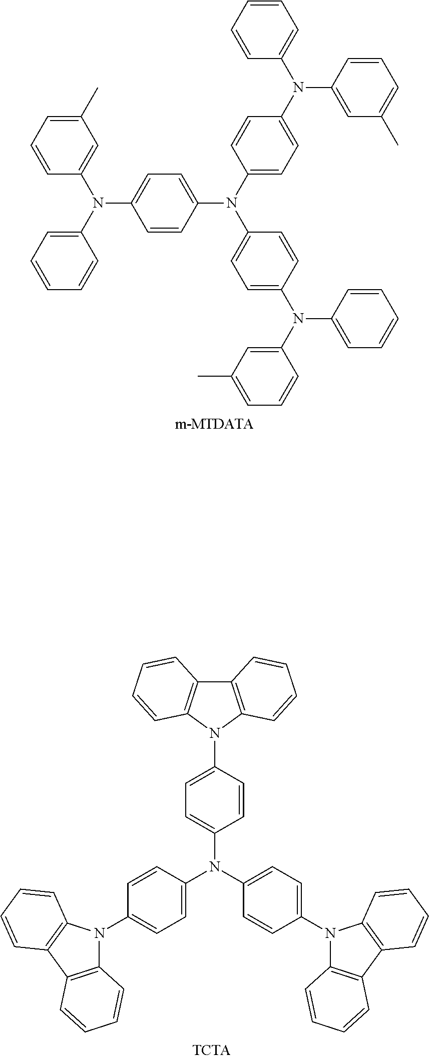 [SMILES: Cc1cccc(N(c2ccccc2)c2ccc(N(c3ccc(N(c4ccccc4)c4cccc(C)c4)cc3)c3ccc(N(c4ccccc4)c4cccc(C)c4)cc3)cc2)c1 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

In the emission layer 16, the electron transporting host that may form an exciplex may include a π-electron poor heteroaryl compound, a phosphine oxide group-containing compound, a triazine derivative, or a sulfur oxide group-containing compound. The π-electron poor heteroaryl compound includes a heteroaryl group and has a reduced electron density of delocalized π-bonds of the heteroaryl group due to a high electron affinity of a heteroatom. The electron transporting host may include, for example, bis-4,6-(3,5-di-3-pyridylphenyl)-2-methylpyrimidine (B3PYMM), 2,2′,2″-(1,3,5-benzenetriyl)tris-[1-phenyl-1H-benzimidazole] (TPBi), tris(2,4,6-triMethyl-3-(pyridin-3-yl)phenyl)borane (3TPYMB), 1,3-bis[3,5-di(pyridin-3-yl)phenyl]benzene (BmPyPB), 3,3′-[5′-[3-(3-Pyridinyl)phenyl][1,1′:3′,1″-terphenyl]-3,3″-diyl]bispyridine (TmPyPB), BSFM (see the corresponding formula below), PO-T2T (see the corresponding formula below), or dibenzo[b,d]thiophene-2,8-diylbis(diphenylphosphine oxide) (PO15), but embodiments are not limited thereto.

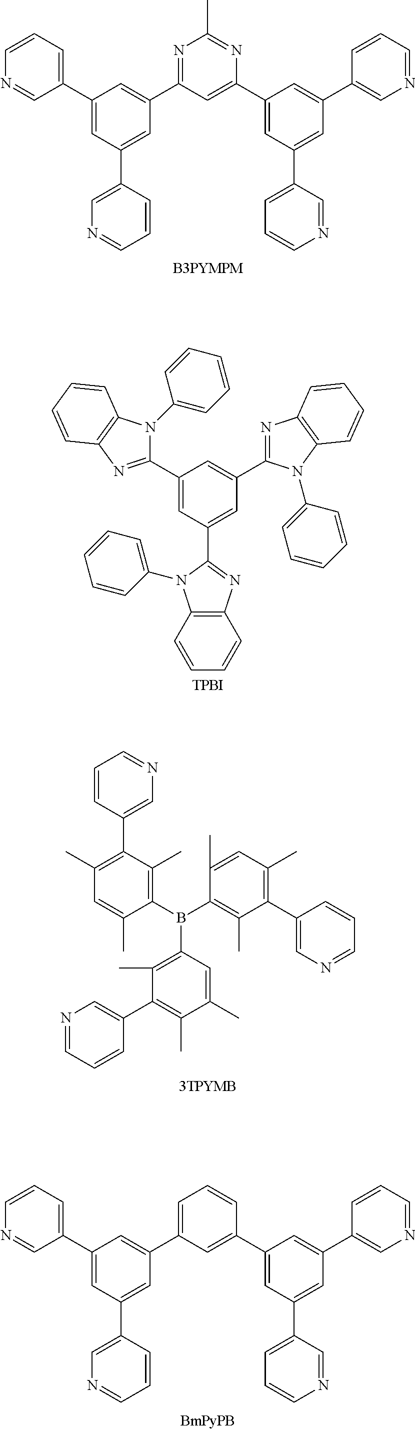

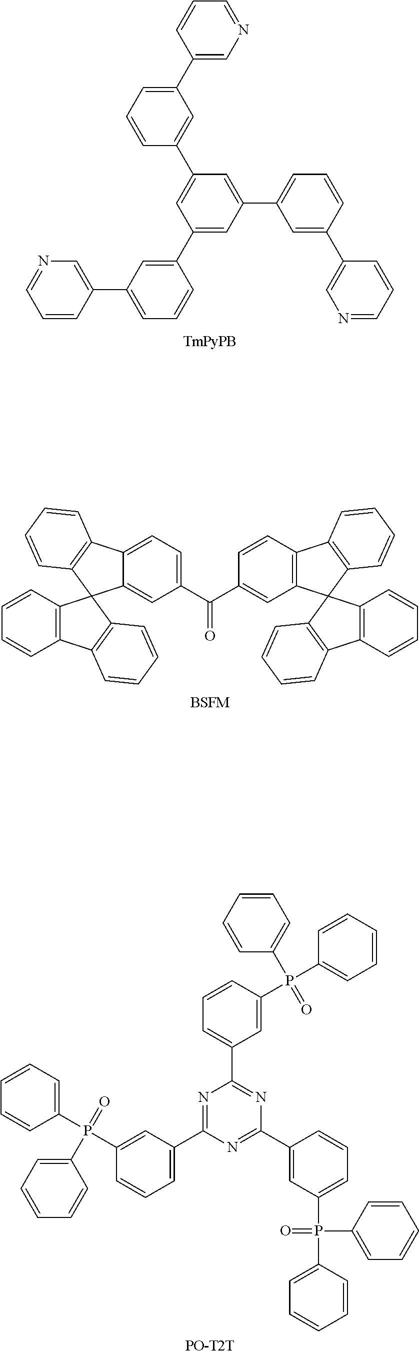 [SMILES: c1cncc(-c2cccc(-c3cc(-c4cccc(-c5cccnc5)c4)cc(-c4cccc(-c5cccnc5)c4)c3)c2)c1 ; O=C(c1ccc2c(c1)C1(c3ccccc3-c3ccccc31)c1ccccc1-2)c1ccc2c(c1)C1(c3ccccc3-c3ccccc31)c1ccccc1-2 ; O=P(c1ccccc1)(c1ccccc1)c1cccc(-c2nc(-c3cccc(P(=O)(c4ccccc4)c4ccccc4)c3)nc(-c3cccc(P(=O)(c4ccccc4)c4ccccc4)c3)n2)c1 ; "PO-T2T"]

The dopant is a material that emits delayed fluorescent light. The delayed fluorescent light is fluorescent light that emits at a singlet excitation state (S₁) by converting excitons from a triplet excitation state (T₁) to a singlet excitation state (S₁). The delayed fluorescent light has the same peak locations as those of an emission spectrum but is different from fluorescent light in terms of having a long decay time. Also, although the delayed fluorescent light has a long decay time, the delayed fluorescent light is different from phosphorescent light since peak locations of an emission spectrum differ as much as the S1−T1 energy difference of a phosphorescent spectrum.

Triplet excitation energy of the delayed fluorescent dopant is lower than triplet excitation energy of the exciplex formed by the mixed host. Also, an overlapping area formed by curves of an absorption spectrum of the delayed fluorescent dopant and an emission spectrum of the exciplex is large. Here, since the overlapping area formed by the curves of the spectrums is large, energy may be fluently transferred from the host exciplex to the delayed fluorescent dopant.

Singlet excitation energy of the dopant may be higher than triplet excitation energy of the dopant. Also, triplet excitation energy of the dopant may be lower than triplet excitation energy of the hole transporting host and triplet excitation energy of the electron transporting host.

The delayed fluorescent dopant may include a fluorescent organic material in the form of D-C-A (an electron donating group:D-a connecting group:C-an electron accepting group:A), in the form D-C-A-C-D, or in the form A-C-D-C-A, but embodiments are not limited thereto. For example, the form of D-C-A is a structure including an electron donating group (D) linked to an electron accepting group (A) via a connecting group (C). For example, the form of D-C-A-C-D includes one electron donating group (D) linked to an electron accepting group (A) via one connecting group (C) and another electron donating group (D) linked to the electron accepting group (A) via another connecting group (C). For example, the form of A-C-D-C-A includes one electron accepting group (A) linked to a electron donating group (D) via one connecting group (C) and another electron accepting group (A) linked to the electron donating group (D) via another connecting group (C).

Examples of the electron donating group (D) may include a carbazole-based group or an aromatic amine-based group.

Examples of the electron accepting group (A) may include a pyridine-based group, a pyrrole-based group, a triazine-based group, a phosphine oxide-based group, or a sulfur oxide-based group.

Examples of the connecting group (C) may include a phenylene group or a naphthylene group.

Examples of the delayed fluorescent dopant may include 4CzIPN, 2CzPN, 4CzTPN-Ph, DMAC-DPS, or PXZ-DPS.

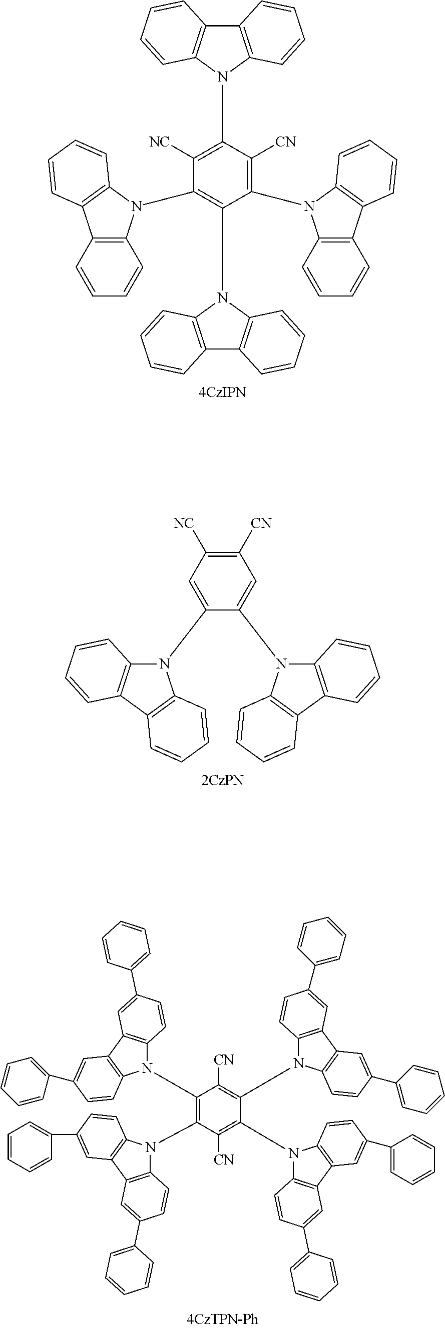 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; N#Cc1cc(-n2c3ccccc3c3ccccc32)c(-n2c3ccccc3c3ccccc32)cc1C#N ; N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

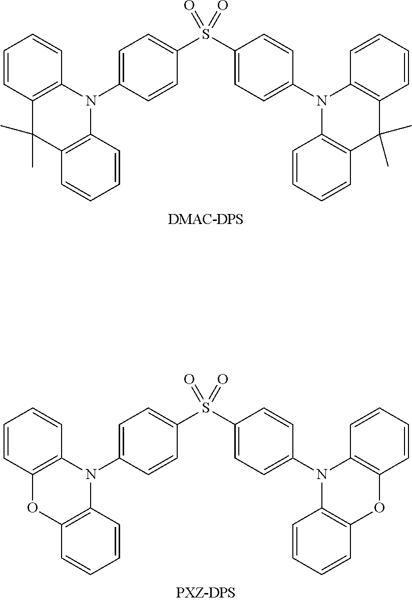

The organic light-emitting device 10 uses a co-host of the hole transporting host and the electron transporting host to lower an energy barrier when holes and electrons are injected to the emission layer 16, and since the hole transporting host and the electron transporting host form an exciplex, the organic light-emitting device 10 may have a low driving voltage and a high efficiency without roll-off at a high luminance. Also, since the organic light-emitting device 10 uses a delayed fluorescent dopant, internal quantum efficiency improves, and thus the organic light-emitting device 10 may have a high emission efficiency.

A weight ratio of the mixed host to the delayed fluorescent dopant in the organic layer 15 of the organic light-emitting device 10 may be in a range of about 99:1 to about 80:20. When the weight ratio of the mixed host to the delayed fluorescent dopant is within this range, energy transfer and emission occurring in the organic light-emitting device 10 may be satisfactory.

Examples of the combination of the hole transporting host and the electron transporting host that together form an exciplex may include mCP:B3PYMPM, TCTA:B3PYMPM, TCTA:TPBi, TCTA:3TPYMB, TCTA:BmPyPB, TCTA:BSFM, CBP:B3PYMPM, and NPB:BSFM.

Examples of the dopant material emitting the delayed fluorescent light may include 4CzIPN, 2CzPN, 4CzTPN-Ph, DMAC-DPS, and PXZ-DPS, but embodiments are not limited thereto.

FIG. 2 is a cross-sectional view schematically illustrating a structure of an organic light-emitting device 20 according to another exemplary embodiment.

The organic light-emitting device includes a first electrode 21, a second electrode 29 facing the first electrode 21, and an organic layer 25 that is disposed between the first electrode 21 and the second electrode 29. The organic layer 25 includes an emission layer 26, a hole transport layer 23 that is disposed between the emission layer 26 and the first electrode 21, a hole injection layer 22 that is disposed between the hole transport layer 23 and the first electrode 21, an electron transport layer 27 that is disposed between the emission layer 26 and the second electrode 29, and an electron injection layer 28 that is disposed between the electron transport layer 27 and the second electrode 29. Here, at least one of the hole injection layer 22 and the electron injection layer 28 may be omitted. Also, a buffer layer (not shown) may be further disposed between the emission layer 26 and the hole transport layer 23 or between the emission layer 26 and the electron transport layer 27.

The organic light-emitting device 20 may further include a substrate (not shown). The substrate (not shown) may be a substrate that is used in a general organic light-emitting device or may be a glass substrate or a transparent plastic substrate, with excellent mechanical strength, thermal stability, transparency, surface smoothness, tractability, and waterproofness.

The first electrode 21 may be a transparent electrode or reflective electrode, and when the organic light-emitting device 20 is a top emission type, the first electrode 21 may be a transparent electrode. The transparent electrode may include ITO, IZO, ZnO, or graphene. When the first electrode 21 is a reflective electrode, the reflective electrode may be prepared by forming a reflection layer formed of Ag, Mg, Al, Pt, Pd, Au, Ni, Nd, Ir, Cr, or a compound thereof, and then forming another layer formed of ITO, IZO, ZnO, or graphene on the reflective layer. The first electrode 21 may be formed by using a commonly known method, such as deposition, sputtering, or spin-coating.

The hole injection layer 22 may be formed on the first electrode 11 by using various methods such as vacuum deposition, spin coating, casting, or a Langmuir-Blodgett (LB) method. The hole injection layer 22 may include a general hole injection material, and examples of the hole injection material may include a phthalocyanine compound such as copper phthalocyanines, m-MTDATA, TDATA, 4,4′-Cyclohexylidenebis[N,N-bis(4-methylphenyl)benzenamine] (TAPC), 4,4′,4″-Tris[2-naphthyl(phenyl)amino]triphenylamine (2-TNATA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), or polyaniline)/poly(4-styrenesulfonate) (PANI/PSS), but embodiments are not limited thereto.

The hole transport layer 23 may include the hole transporting host of the emission layer 26. Also, the hole transport layer 23 may include a general hole transporting host, such as TPD, NPB, α-NPD, or TCTA. The hole transport layer 23 may be formed by using various methods such as vacuum deposition, spin coating, casting, or an LB method.

The emission layer 26 includes the hole transporting host that forms an exciplex, the electron transporting host, and the delayed fluorescent dopant. The emission layer 26 of the organic light-emitting device 20 has the same structure with that of the emission layer 16 of the organic light-emitting device 10. The emission layer 26 may be formed by using various methods such as vacuum deposition, spin coating, casting, or an LB method.

The electron transport layer 27 may include the electron transporting host of the emission layer 26. Also, the electron transport layer 27 may include a general hole transporting host, such as Alq₃, bathocuproine (BCP), 4,7-diphenyl-1,10-phenanthroline (Bphen), 3-(biphenyl-4-yl)-5-(4-tert-butylphenyl)-4-phenyl-4H-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (Balq), bis(10-hydroxybenzo[h]quinolinato)beryllium (Bebq₂), or 9,10-di(naphth-2-yl)anthracene (AND). The electron transport layer 27 may be formed by using various methods such as vacuum deposition, spin coating, casting, or an LB method.

The electron injection layer 28 may be formed by using a material, such as LiF, NaCl, CsF, Li₂O, or BaO. The electron injection layer 28 may be formed by using various methods such as vacuum deposition, spin coating, casting, or an LB method.

The second electrode 29 may have a structure including an alkali metal such as lithium, sodium, potassium, rubidium, or cesium; an alkali earth metal such as beryllium, magnesium, calcium, strontium, or barium; a metal such as aluminum, scandium, vanadium, zinc, yttrium, indium, cerium, samarium, europium, terbium, or ytterbium; an alloy of at least two selected therefrom; an alloy of at least one selected therefrom and at least one selected from gold, silver, platinum, copper, manganese, titanium, cobalt, nickel, tungsten, or tin; or at least two selected therefrom. Optionally, UV-ozone treated ITO may be used to form the second electrode 29. Examples of the alloy may include indium tin oxide (ITO), indium zinc oxide (IZO), zinc oxide (ZnO), or graphene. When the organic light-emitting device 20 is a top emission type, the second electrode 29 may include a transparent oxide such as ITO, IZO, ZnO, or graphene. The second electrode 29 may be formed by using various methods such as vacuum deposition, sputtering, or spin coating.

Thereinafter, one or more embodiments will be described in detail with reference to the following examples. However, these examples are not intended to limit the scope of the one or more embodiments.

### EXAMPLE

Organic materials were available from Daejoo Electronic Materials Co., Ltd., and LiF was available from Materion Corporation.

Current densities, luminances, and source meters were measured with a source meter (Keithley 2400) and spectrophotometer (Spectrascan CS100, available from Photo Research). Also, angular distribution of the EL was measured with a programmable source meter (Keithley 2400) and a fiber optic spectrometer (Ocean Optics S2000). External quantum efficiencies and electric power efficiency of the organic light-emitting devices were calculated from current density to voltage to obtain luminance characteristics and each distribution of the EL spectrum and EL intensity.

### Example 1

An organic light-emitting device having the following components was prepared.

ITO (70 nm)/4 wt % ReO₃:96 wt % mCP (45 nm)/mCP (40 nm)/mCP:B3PYMPM:5 wt % 4CzIPN (30 nm)/B3PYMPM (20 nm)/4% Rb₂Co₃:B3PYMPM (30 nm)/Al (100 nm)

As an anode, a glass substrate on which ITO was patterned at a thickness of about 700 Å was used. The ITO glass substrate was pre-washed with isopropyl alcohol and acetone, and then was exposed to UV-ozone for 10 minutes. Next, 4 wt % ReO₃ and 96 wt % mCP were co-deposited on the ITO glass substrate to form a hole injection layer having a thickness of 450 Å. Then, mCP was deposited on the hole injection layer to form a hole transport layer having a thickness of 400 Å. mCP, B3PYMPM, and 4CzIPN were co-deposited on the hole transport layer at a weight ratio of 47.5:47.5:5 to form an emission layer having a thickness of 300 Å. Then, B3PYMPM was deposited on the emission layer to form an electron transport layer having a thickness of 500 Å. Next, LiF was deposited on the electron transport layer to form an electron injection layer having a thickness of 10 Å, and then Al was deposited thereon to form a cathode having a thickness of 1000 Å. Here, each of the layers was thermally deposited in vacuum maintained at 5×10⁻⁷ Torr.

### Example 2

An organic light-emitting device having the following components was prepared.

ITO (70 nm)/TAPC (75 nm)/TCTA (10 nm)/TCTA:B3PYMPM:2 wt % 4CzIPN (30 nm)/B3PYMPM (50 nm)/LiF (1 nm)/Al (100 nm)

As an anode, an ITO glass substrate having a thickness of 700 Å was used, and TAPC was vacuum-deposited on the ITO glass substrate to form a hole injection layer having a thickness of 750 Å. Then, TCTA was vacuum-deposited on the hole injection layer to form a hole transport layer having a thickness of 100 Å. Next, TCTA, B3PYMPM, and 4CzIPN were co-deposited at a weight ratio of 49:49:2 on the hole transport layer to form an emission layer having a thickness of 300 Å. Then, B3PYMPM was vacuum-deposited on the emission layer to form an electron transport layer having a thickness of 500 Å. Subsequently, LiF was vacuum-deposited on the electron transport layer to form an electron injection layer having a thickness of 10 Å, and Al was vacuum-deposited thereon to form a cathode having a thickness of 1000 Å.

Energy Diagram

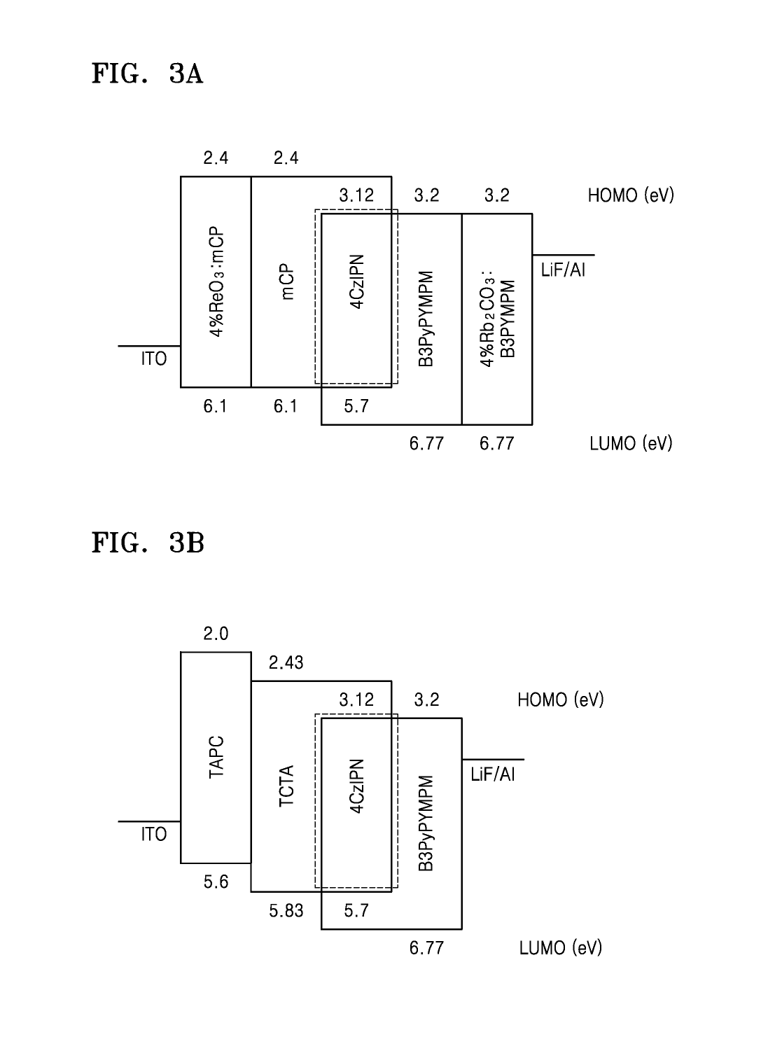

FIGS. 3A and 3B are diagrams of highest occupied molecular orbital (HOMO) and lowest occupied molecular orbital (LUMO) values of layer structures of the organic light-emitting devices prepared in Examples 1 and 2, respectively.

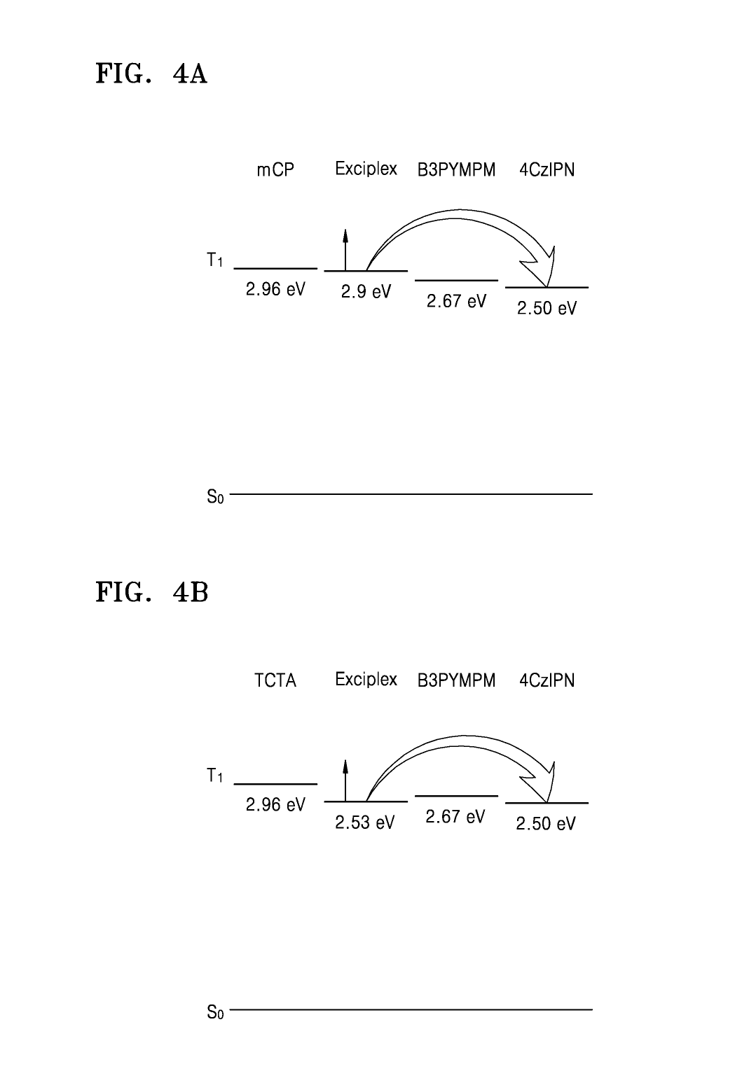

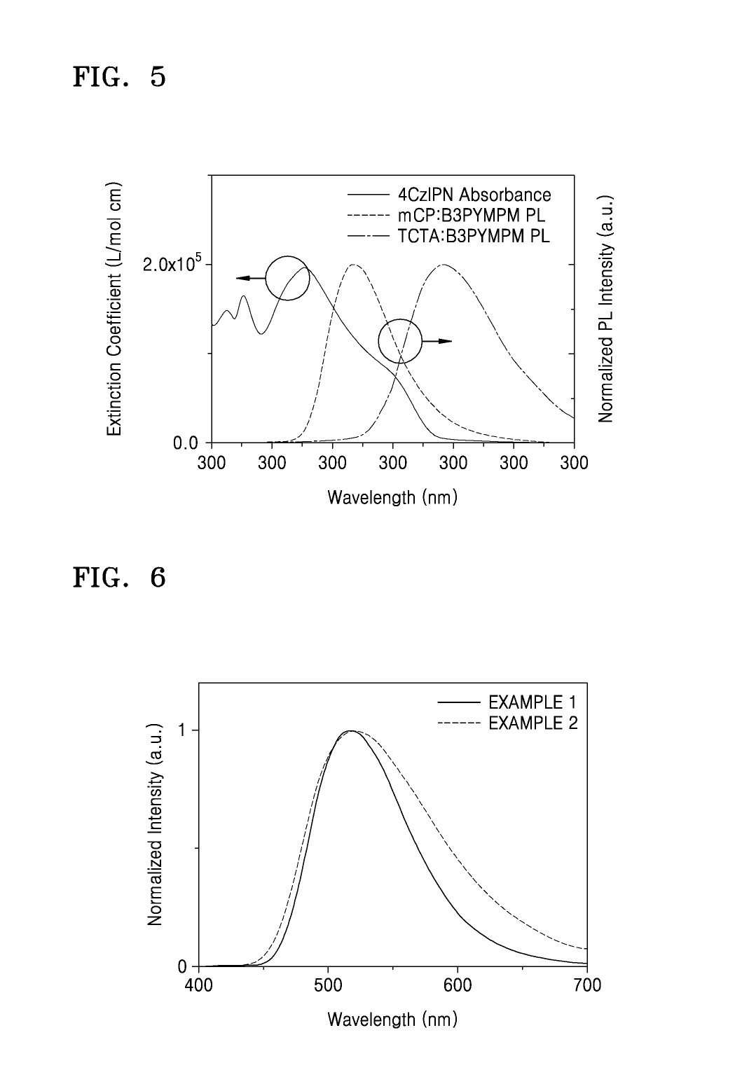

FIG. 4A is an energy diagram showing triplet excitation energy levels (T1) of an exciplex host and a dopant used in the organic light-emitting device of Example 1. Referring to FIG. 4A, a triplet excitation energy level of 4CzIPN (a dopant), 2.497 eV, is lower than a triplet excitation energy level of mCP: B3PYMPM (an exciplex host), 2.9 eV. In this regard, since a difference between the triplet excitation energy levels of the dopant and the exciplex host is significant, the triplet excitation energy of the dopant may not be transferred to the triplex excitation energy of the exciplex host, and thus it may be expected that the organic light-emitting device prepared in Example 1 may well enclose excitons in the dopant of the emission layer.

FIG. 4B is an energy diagram showing triplet excitation energy levels (T1) of an exciplex host and a dopant used in the organic light-emitting device of Example 2. Referring to FIG. 4B, a triplet excitation energy level of 4CzIPN (a dopant), 2.497 eV, is close to a triplet excitation energy level of TCTA:B3PYMPM (an exciplex host), 2.53 eV. In this regard, since a difference between the triplet excitation energy levels of the dopant and the exciplex host is not significant, the triplet excitation energy of the dopant may be easily transferred to the triplex excitation energy of the exciplex host, and thus it may be expected that the organic light-emitting device prepared in Example 2 may not well enclose excitons in the dopant of the emission layer.

FIG. 5 shows an absorption spectrum of 4CzIPN and a photoluminescence spectrum of a mCP:B3PYMPM exciplex and a TCTA:B3PYMPM exciplex. Obtaining the absorption spectrum and the photoluminescence spectrum of FIG. 5 was performed in a solution. As a solvent of the solution, methylene chloride (MC) was used, and an amount of a solute in the solution was 0.05 mM. A singlet excitation level of 4CzIPN was determined from the absorption spectrum of 4CzIPN shown in FIG. 5, and when ΔE_{ST}(ΔE_{ST}=E_{S1}−E_{T1}, which is a difference between singlet and triplet) is subtracted from the singlet excitation level, a triplet excitation level of 4CzIPN may be obtained.

Referring to FIG. 5, an area where the absorption spectrum of 4CzIPN overlaps the photoluminescence spectrum of the mCP:B3PYMPM exciplex is significantly large, and this indicates that energy transfer from the exciplex host to the dopant may be efficient. Whereas, an area of the absorption spectrum of 4CzIPN that overlaps the photoluminescence spectrum of the TCTA:B3PYMPM exciplex is significantly small, and this indicates that energy transfer from the exciplex host to the dopant may not be efficient.

FIG. 6 shows luminescent spectra of the organic light-emitting devices prepared in Examples 1 and 2. Referring to FIG. 6, a peak wavelength of the emission layer of mCP:B3PYMPM:4CzIPN in Example 1 is 507 nm, and a peak wavelength of the emission layer of TCTA:B3PYMPM:4CzIPN in Example 2 is 516 nm, and both lights emitted from the emission layers of Example 1 and Example 2 are both green light.

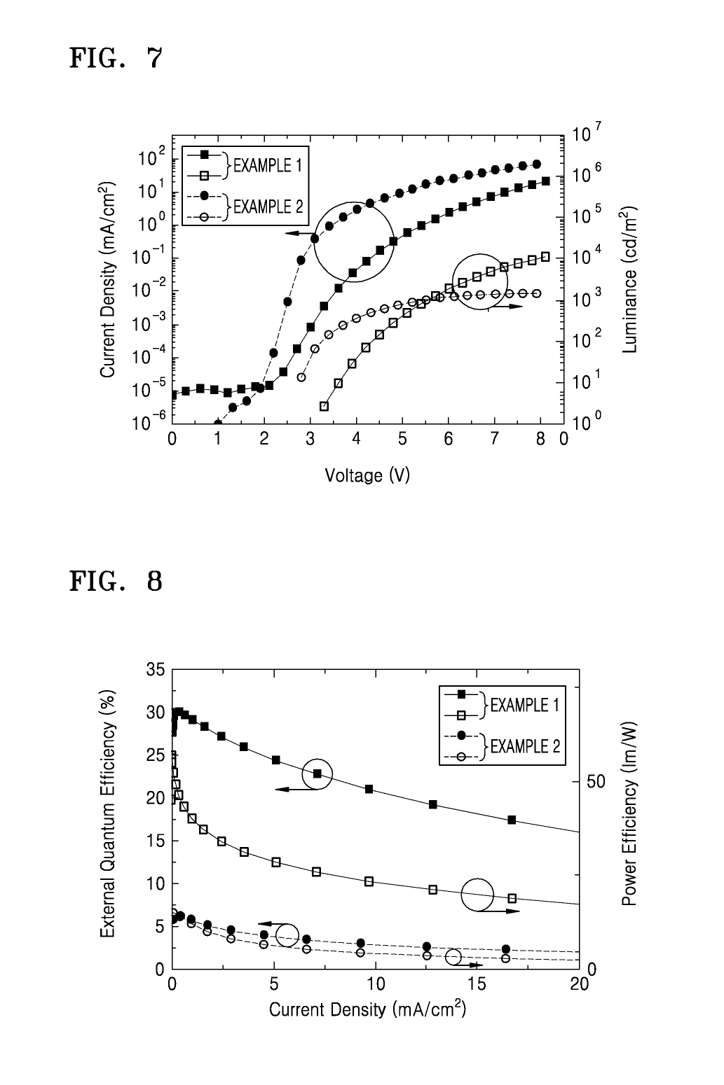

FIG. 7 shows a graph of a current density verses a voltage and a graph of a voltage verses a luminescence of the organic light-emitting devices prepared in Examples 1 and 2.

In FIG. 7, a driving voltage of the organic light-emitting device of Example 1 is 3.3 V, and a driving voltage of the organic light-emitting device of Example 2 is 2.7 V. In spite of the low driving voltage, a current density and a luminance of the organic light-emitting device of Example 2 may decrease in a relatively rapid manner according to an increase in the applied voltage, and this indicates that a large amount of the injected electrons and holes were used for non-emission recombination.

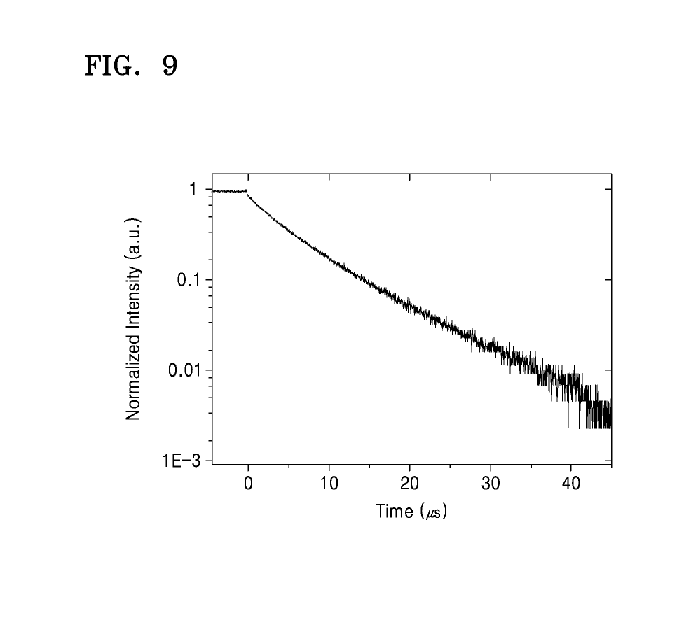

FIG. 8 shows a graph of an external quantum efficiency and an electrical power efficiency of the organic light-emitting devices prepared in Examples 1 and 2. In the graph in FIG. 8, an external quantum efficiency of the organic light-emitting device of Example 1, 30.1%, is higher than an external quantum efficiency of the organic light-emitting device of Example 2, 6.1%. Thus, an electric power efficiency of the organic light-emitting device of Example 1 is further higher than an electric power efficiency of the organic light-emitting device of Example 2 as well. As described above, it is deemed that the low external quantum efficiency of the organic light-emitting device of Example 2 is mainly due to the triplet excitation energy level of the TCTA:B3PYMPM exciplex found close to the triplet excitation energy level of 4CzIPN. When a triplet excitation energy level of an exciplex host is close to a triplet excitation energy level of a dopant, which is a light-emitting material, enclosing excitons in the dopant may be prevented. Meanwhile, in the case of the organic light-emitting device of Example 1, since a triplet excitation energy level of the mCP:B3PYMPM exciplex is too far from the triplet excitation energy level of 4CzIPN which forms a high barrier, excitons may be easily enclosed in the dopant, and thus an external quantum efficiency and an electric power efficiency may increase. The organic light-emitting device of Example 1 has the maximum external quantum efficiency of 30.1%, and this is the highest value among the reported values for a fluorescent organic light-emitting device.

Also, a layer (mCP:B3PYMPM:5 wt % 4CzIPN, 30 nm) same as the emission layer of the organic light-emitting device of Example 1 was formed on a silica substrate, and the substrate was photoexcited to obtain a high photoluminescence quantum yield (PLQY) of 97%. This proves that energy transfer from the exciplex host to the dopant was successful, and thus the energy transfer contributed in achieving the high internal quantum efficiency.

FIG. 9 is an electroluminescence decay curve of the organic light-emitting device prepared in Example 1. In FIG. 9, a long tail of the curve denotes that the emitted light is delayed fluorescent light that is generated by reverse intersystem crossing. It may be known that the delayed fluorescent light contributed in obtaining the high internal quantum efficiency.

As described above, according to the one or more of the above embodiments, an organic light-emitting device may have a high external quantum efficiency and improved roll-off characteristics by using an exciplex host and a delayed fluorescent dopant in an emission layer.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope of the inventive concept as defined by the following claims.

What is claimed is:

1. An organic light-emitting device comprising
a first electrode;
a second electrode facing the first electrode; and
an emission layer that is disposed between the first electrode and the second electrode and comprises a mixed host and a dopant,
wherein the mixed host comprises a hole transporting host and an electron transporting host which together form an exciplex, and
the dopant comprises a compound that emits delayed fluorescent light.

2. The organic light-emitting device of claim 1, wherein triplet excitation energy of the dopant is lower than triplet excitation energy of the exciplex, and an overlapping area formed by curves of an absorption spectrum of the dopant and an emission spectrum of the exciplex is large.

3. The organic light-emitting device of claim 1, wherein triplet excitation energy of the dopant is lower than triplet excitation energy of the hole transporting host and triplet excitation energy of the electron transporting host.

4. The organic light-emitting device of claim 1, wherein singlet excitation energy of the dopant is higher than triplet excitation energy of the dopant.

5. The organic light-emitting device of claim 1, wherein the dopant in the emission layer comprises a delayed fluorescent organic material in the form of D-C-A (an electron donating group:D-a connecting group:C-an electron accepting group:A), in the form of D-C-A-C-D, or in the form of A-C-D-C-A.

6. The organic light-emitting device of claim 1, wherein the hole transporting host comprises an aromatic amine compound or a carbazole derivative.

7. The organic light-emitting device of claim 1, wherein the electron transporting host comprises a π-electron poor heteroaromatic ring.

8. The organic light-emitting device of claim 1, wherein the electron transporting host comprises a phosphine oxide group-containing compound, a triazine derivative, or a sulfur oxide group-containing compound.

9. The organic light-emitting device of claim 1, further comprising a hole transporting region between the first electrode and the emission layer.

10. The organic light-emitting device of claim 1, further comprising an electron transporting region between the emission layer and the second electrode.

11. The organic light-emitting device of claim 9, wherein the hole transporting region comprises the hole transporting host.

12. The organic light-emitting device of claim 10, wherein the electron transporting region comprises the electron transporting host.
